(19) United States
(12) Patent Application Publication
(10) Pub. No.: US 2009/0007959 A1
(43) Pub. Date: Jan. 8, 2009

(54) Multi-leaf solar energy supplying apparatus

(76) Inventors: Wan-Hua Wu, Taipei City (TW); Shih-Wei Tung, Taipei City (TW); Hsin-Wen Lin, Taipei City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/822,316

(22) Filed: Jul. 5, 2007

(51) Int. Cl. H01L 31/058; H01L 31/045; H01L 31/055

(52) U.S. Cl. 136/248

(57) ABSTRACT

A multi-leaf solar energy supplying apparatus includes an energy converting module and an electrical power storing module. The energy converting module includes a solar energy board having a plurality of leaves for converting solar energy into electrical power. The electrical power storing module is electrically connected with the energy converting module for receiving electrical power to charge a secondary battery. Therefore, the secondary battery provides at least one output voltage to an application system. Furthermore, the energy converting module further includes at least one first power transmission port. When the energy converting module is separated from the electrical power storing module, the energy converting module is connected with the application system via the first power transmission port and provides a voltage to the application system. Thereby, the goals of charging and supplying power via solar power, and offering a power source that can be used anywhere are achieved.

### BACKGROUND OF THE INVENTION

1. Field of the Invention

The present invention relates to a solar energy supplying apparatus. In particular, this invention relates to a solar energy supplying apparatus in which the leaves can be unfolded and folded.

2. Description of the Related Art

Because industry and technology has become highly developed in the last two hundred years, our way of living and our environment has changed. Recently, energy shortages have become a top issue. In order to cope with the need for energy, an energy developing industry has arisen. Furthermore, because people pay much attention nowadays to environmental protection and quality of life issues, people do not wish to use chemical materials that will damage the environment in the process of developing energy. Solar energy is an excellent, renewable source of energy that meets the requirements of environmental protection.

There are a variety of products that relate to solar energy in our daily life. However, converting solar energy into electrical power is implemented by shining sunlight on a solar energy board for a long time. The bigger the receiving area is, the more power can be generated. The dimensions of solar energy products are usually very large and must be located on a specified location or object. If not they can only be applied to a product that requires small amounts of power.

However, in order to continuously operate a digital portable device or other such portable devices, the consumer has to prepare a spare battery and carry it around. It is an additional expense for the consumer. Furthermore, for a user that needs to operate the portable devices in outdoors for long periods, preparing a spare battery cannot fully overcome the problem.

Therefore, how to supply energy anytime, anywhere and not destroy the environment in the process while meeting consumer requirements is an issue seeking a solution.

### SUMMARY OF THE INVENTION

One particular aspect of the present invention is to provide a multi-leaf solar energy supplying apparatus. The present invention uses two independent modules. When the two modules are assembled together, it charges the battery to an energy source for a fixed location. When the two modules are separated, the module used for receiving solar energy is connected with the user's device for directly receiving solar energy and converting it into electrical power. Thereby, the present invention fully utilizes solar energy to charge the battery or supply power. Furthermore, the module used for receiving solar energy can be unfolded to receive solar energy over a larger area, and can be folded to reduce the module's dimensions when being carried.

The multi-leaf solar energy supplying apparatus includes an energy converting module, and an electrical power storing module. The energy converting module includes a solar energy board having a plurality leaves, and at least one first power transmission port. The solar energy board receives solar energy and converts it into electrical power. Electrical power is outputted by the first power transmission port to form a first voltage. The electrical power storing module is electrically plugged with the energy converting module, and includes a secondary battery, a charging circuit, and a control unit. The charging circuit is used for charging the secondary battery to store electrical power in the secondary battery. The control unit is electrically connected with the secondary battery to adjust the secondary battery for generating at least one second voltage. Thereby, the energy converting module can be plugged with the electrical power storing module to charge and supply solar energy. Furthermore, the energy converting module can be separated from the electrical power storing module for supplying the first voltage to an external application system so that it can be used as a power source anywhere.

For further understanding of the invention, reference is made to the following detailed description illustrating the embodiments and examples of the invention. The description is only for illustrating the invention and is not intended to be considered limiting of the scope of the claim.

### BRIEF DESCRIPTION OF THE DRAWINGS

The drawings included herein provide a further understanding of the invention. A brief introduction of the drawings is as follows:

FIG. 1 is a block diagram of the multi-leaf solar energy supplying apparatus of the present invention;

FIG. 2 is a schematic diagram of the multi-leaf solar energy supplying apparatus of the first application embodiment of the present invention; and

FIG. 3 is a schematic diagram of the multi-leaf solar energy supplying apparatus of the second application embodiment of the present invention.

### DETAILED DESCRIPTION OF THE PREFERRED EMBODIMENTS

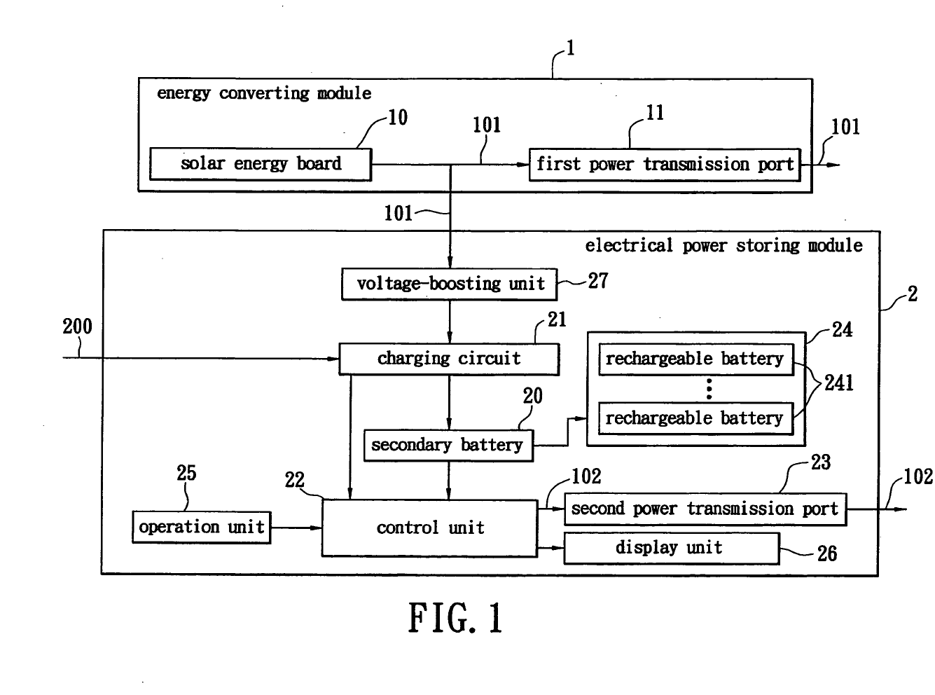

Reference is made to FIG. 1, which shows a block diagram of the multi-leaf solar energy supplying apparatus of the present invention. The multi-leaf solar energy supplying apparatus includes an energy converting module 1, and an electrical power storing module 2. The energy converting module 1 and the electrical power storing module 2 can be assembled together or be separated according to the user's requirements. The energy converting module 1 includes a solar energy board 10, and at least one first power transmission port 11. The solar energy board 10 can be a solar energy board 10 having a plurality of leaves. The leaves are electrically connected with each other in serial to form a larger solar energy receiving area so that the solar energy board 10 can convert more solar energy into electrical power.

The first power transmission port 11 is electrically connected with the solar energy board 10 for transmitting electrical power outputted from the solar energy board 10 to form a first voltage 101 and supply it to an external application system (not shown in the figure). In this embodiment, the first voltage 101 can be 5 volts. In order to easily supply the first voltage 101 to the application system, the first power transmission port 11 can be a USB port. For example, when the application system is a cell phone, the cell phone can be charged via a USB cord. Therefore, when the electrical power of the cell phone is exhausted, the user can directly connect the cell phone with the first power transmission port 11 to receive electrical power via the solar energy board 10 to charge the cell phone. Therefore, the user can continuously operate the cell phone.

The user can determine whether the electrical power storing module 2 is plugged into the energy converting module 1 according to their requirements to receive electrical power converted from solar energy. The electrical power storing module 2 includes a secondary battery 20, a charging circuit 21, a control unit 22, and a voltage-boosting unit 27. When the electrical power storing module 2 is plugged into the energy converting module 1, the voltage-boosting unit 27 is electrically connected with the energy converting module 1 to boost and regulate the first voltage 101 to meet the voltage required by the charging circuit 21. The charging circuit 21 is electrically connected with the voltage-boosting unit 27 to receive the first voltage 101 and store electrical power converted by the solar energy board 10 in the secondary battery 20. The control unit 22 is electrically connected with the secondary battery 20 to adjust the secondary battery 20 for generating at least one second voltage 102. The secondary battery 20 can be a lead-acid battery. The electrical power storing module 2 furthermore includes a second power transmission port 23 electrically connected with the control unit 22 to transmit the second voltage 102 to the application system.

Furthermore, the electrical power storing module 2 further includes a charging battery unit 24, an operation unit 25, and a display unit 26. The charging battery unit 24 can receive at least one rechargeable battery 241, and is electrically connected with the secondary battery 20. When the charging circuit 21 charges the secondary battery 20, the electrical power can be stored in the rechargeable battery 241. In other words, the charging circuit 21 both charges the secondary battery 20 located in the electrical power storing module 2 and the rechargeable battery 241 in the charging battery unit 24. Therefore, the user has different electrical power sources. The rechargeable battery 241 is a Nickel-metal Hydride battery labeled by 2, 3, or 4.

The operation unit 25 is electrically connected with the control unit 22. The user controls the control unit 22 via an external operation to adjust the second battery 20 for changing the magnitude of the second voltage 102. This means that the user uses the operation unit 25 to input a control operation to control the control unit 22 to adjust the magnitude of the second voltage 102 according to the required voltage for the application system. The proper second voltage 102 is transmitted to the application system via the second power transmission port 23. Moreover, the operation unit 25 can be a pressing-key or a knob design.

The display unit 26 is electrically connected with the control unit 22. The control unit 22 has a built-in voltage detector for detecting the voltage level of the secondary battery 20 and controlling the display unit 26 to display the power status and the charging status of the secondary battery 20. When the user uses the operation unit 25 to adjust the second voltage 102, the control unit 22 also controls the display unit 26 to synchronously display the magnitude of the second voltage 102. Furthermore, the control unit 22 has a built-in timer (not shown in the figure) to control the display unit 26 to display the counted time. The required voltage for the control unit 22 is also provided by the charging circuit 21. The display unit 26 can be a pure screen, or a displaying or indicating effect formed by a plurality of different LEDs.

When the amount of sunlight is inadequate, or the energy converting module 1 is separated from the electrical power storing module 2 so that the electrical power storing module 2 cannot receive the electrical power converted by the energy converting module 1 to charge the secondary battery 20 or the charging battery 241, the electrical power storing module 2 can directly connect with a household electrical power 200 to let the charging circuit 21 receive electrical power from the household electrical power 200 to charge the secondary battery 20 or the charging battery 241. Thereby, the energy converting module 1 can cooperate with the electrical power storing module 2 when they are assembled together. When the energy converting module 1 is separated from the electrical power storing module 2, both have their own individual functions.

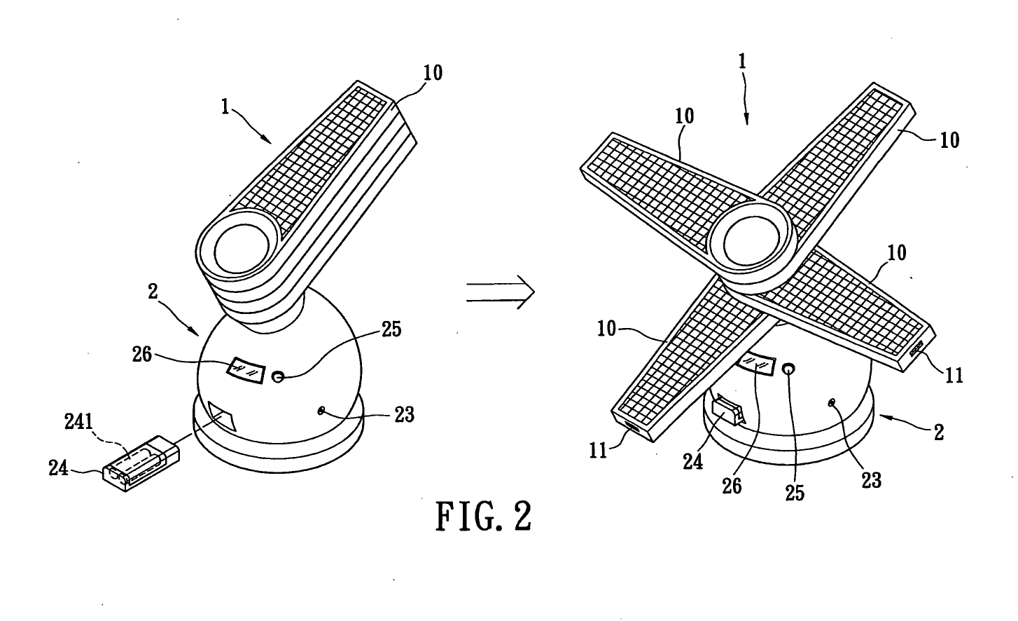

Reference is made to FIG. 2, which shows a schematic diagram of the multi-leaf solar energy supplying apparatus of the first application embodiment of the present invention. In this embodiment, the energy converting module 1 is electrically connected with the electrical power storing module 2. When the solar energy charging process is not being executed, the leaves of solar energy board 10 can be folded to reduce its occupied space, as shown on the left side of FIG. 2. When the solar energy charging process is being executed, the leaves of the solar energy board 10 can be unfolded to increase the area upon which sunlight shines, as shown on the right side of FIG. 2. The operation unit 25 on the electrical power storing module 2 has a pressing-key design. The user can control the magnitude of the second voltage 102 outputted from the second power transmission port 23 to meet the requirements of the application system. The charging battery unit 24 is filled with a rechargeable battery 241 by the user to charge the rechargeable battery 241. The display unit 26 displays the power status of the secondary battery 20 by a battery figure. When the secondary battery 20 is charging, the charging status is displayed by a marquee method.

When the multi-leaf solar energy supplying apparatus is executing the solar energy charging process, the first power transmission port 11 on the energy converting module 1 can be connected with a USB application system/device to execute the power-supplying or power-charging process via the first power transmission port 11 according to the user's requirement.

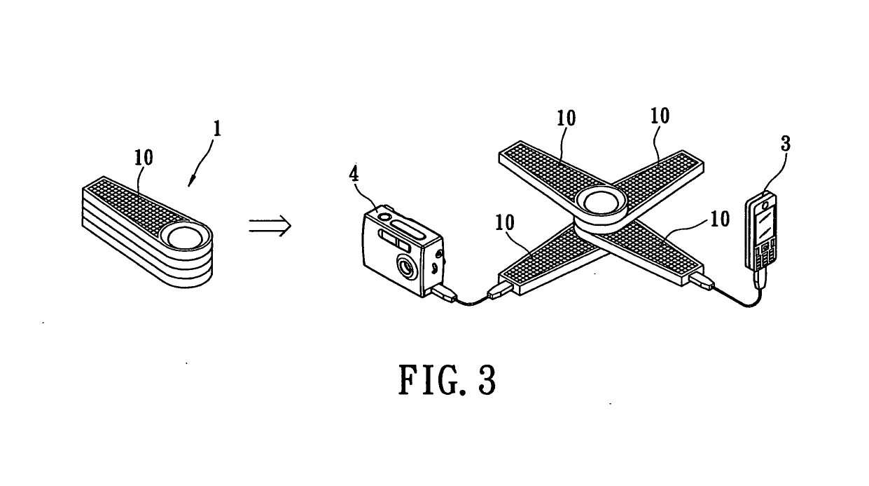

Reference is made to FIG. 3, which shows a schematic diagram of the multi-leaf solar energy supplying apparatus of the second application embodiment of the present invention. In this embodiment, the energy converting module 1 is used as an example. It is a portable module when the energy converting module 1 is separated from the electrical power storing module 2. It is convenient for the user to carry it around when the leaves of solar energy board 10 are folded. When sunlight is shining, if the power of the application system (such as a cell phone 3 or a digital still camera 4) is exhausted, the user can unfold the leaves of the solar energy board 10 and connect the application system with the energy converting module 1 via the first power transmission port 11 so as to receive solar energy that can be used as a power source. Therefore, the user can continuously operate the application system.

In the above embodiment, the first power transmission port 11 that is fastened on the leaves of solar energy board 10 is not used to limit the scope of the present invention, and the quantity and the shape of the leaves of solar energy board 10 is not limited to the above description. The second power transmission port 23, the operation unit 25, or the display unit 26 on the electrical power storing module 2 are also not limited to the above description.

The present invention uses two independent modules, including the energy converting module 1 and the electrical power storing module 2, to allow the two modules to be operated independently. Alternatively, the two modules can be assembled together to execute the power-charging and the power-supplying processes so that electrical power can be supplied at anytime. Because the leaves of the solar energy board 10 can be unfolded, it is convenient for the user to carry the energy converting module 1 around and the required space is small.

The description above only illustrates specific embodiments and examples of the invention. The invention should therefore cover various modifications and variations made to the herein-described structure and operations of the invention, provided they fall within the scope of the invention as defined in the following appended claims.

What is claimed is:

1. A multi-leaf solar energy supplying apparatus, comprising:
an energy converting module having a solar energy board and at least one first power transmission port, wherein the solar energy board is a solar energy board with a plurality leaves for receiving solar energy and converting it into electrical power, and the electrical power is outputted by the first power transmission port to form a first voltage; and
an electrical power storing module electrically connected with the energy converting module, comprising:
a secondary battery;
a charging circuit electrically connected with the energy converting module and the secondary battery for storing electrical power in the secondary battery; and
a control unit electrically connected with the secondary battery for adjusting the secondary battery to generate at least one second voltage.

2. The multi-leaf solar energy supplying apparatus as claimed in claim 1, wherein the first power transmission port is a USB port.

3. The multi-leaf solar energy supplying apparatus as claimed in claim 1, wherein the leaves are unfolded or folded, and the leaves are electrically connected in series.

4. The multi-leaf solar energy supplying apparatus as claimed in claim 1, wherein the first voltage is 5 volts.

5. The multi-leaf solar energy supplying apparatus as claimed in claim 1, wherein the electrical power storing module further comprises a voltage-boosting unit electrically connected with the solar energy board for boosting and regulating the first voltage to meet the required voltage for the charging circuit.

6. The multi-leaf solar energy supplying apparatus as claimed in claim 1, wherein the electrical power storing module further comprises a charging battery unit, the charging battery unit receives at least one rechargeable battery, the charging battery unit is electrically connected with the secondary battery for synchronously storing the electrical power in the rechargeable battery when the secondary battery is being charged.

7. The multi-leaf solar energy supplying apparatus as claimed in claim 6, wherein the charging circuit further receives a household electrical power for charging the secondary battery and the rechargeable battery.

8. The multi-leaf solar energy supplying apparatus as claimed in claim 1, wherein the electrical power storing module further comprises an operation unit electrically connected with the control unit for controlling the control unit to adjust the second voltage generated by the secondary battery.

9. The multi-leaf solar energy supplying apparatus as claimed in claim 8, wherein the operation unit is a press-key or a knob.

10. The multi-leaf solar energy supplying apparatus as claimed in claim 1, wherein the electrical power storing module further comprises a display unit electrically connected with the control unit for receiving a control from the control unit to display a power status, a charging status of the secondary battery or a magnitude of the second voltage.

11. The multi-leaf solar energy supplying apparatus as claimed in claim 10, wherein the control unit is controlled by a timer to display a time on the display unit.

12. The multi-leaf solar energy supplying apparatus as claimed in claim 10, wherein the display unit is a screen or LEDs.

13. The multi-leaf solar energy supplying apparatus as claimed in claim 1, wherein the secondary battery is a lead-acid battery.

14. The multi-leaf solar energy supplying apparatus as claimed in claim 1, wherein the control unit further is electrically connected with at least one second power transmission port for outputting the second voltage.
